(19) United States
(12) Patent Application Publication
(10) Pub. No.: US 2011/0037081 A1
(43) Pub. Date: Feb. 17, 2011

(54) WHITE LIGHT-EMITTING DIODE PACKAGES WITH TUNABLE COLOR TEMPERATURE

(76) Inventors: Wu-Cheng Kuo, Hsinchu (TW); Tzu-Han Lin, Hsinchu (TW)

Correspondence Address: Muncy, Geissler, Olds & Lowe, PLLC, 4000 Legato Road, Suite 310, FAIRFAX, VA, 22033, US

(21) Appl. No.: 12/540,145

(22) Filed: Aug. 12, 2009

(51) Int. Cl. H01L 33/00

(52) U.S. Cl. 257/89; 257/E33.059

(57) ABSTRACT

A white light-emitting diode package with tunable color temperature is provided, including a package substrate with a first light emitting diode (first LED) disposed over a first portion of the substrate and a second light emitting diode (second LED) disposed over a second portion different from the first portion of the substrate. A phosphor layer is coated around the first and second LED, wherein the phosphor layer is formed by blending at least one colored phosphor grain with a transparent optical resin, and the at least one colored phosphor grain in the transparent optical resin is excited by light from the first and second LED to react and emit white light. In one embodiment, the first and second LED are both blue LEDs for emitting blue light of different wavelengths or ultraviolet (UV) LEDs for emitting UV light of different wavelengths.

### BACKGROUND OF THE INVENTION

1. Field of the Invention

The present invention relates to white light sources, and in particular relates to white light-emitting diode (white LED) packages capable of emitting white light with tunable color temperature.

2. Description of the Related Art

The correlated color temperature (CCT) of a white light source is determined by comparing its hue with a theoretical, heated black-body radiator. CCT is specified in Kelvin (K) and corresponds to the temperature of the black-body radiator which radiates the same hue of white light as a CCT light source. Today, the color temperature from a white light source is defined predominantly by the type of light source. For example incandescent light sources always give a relatively low color temperature around 3000K, called “warm white”. Conversely, fluorescent light sources always give a higher color temperature around 7000K, called “cold white”. The choice of warm or cold white light is determined when purchasing the type of light source. In many situations, such as street lighting, warm white and cold white light are used together.

White light emitting diodes (LEDs) are known in the art and are a relatively recent innovation. However, it only became practical to develop white light sources based on LEDs, after LEDS were able to efficiently emit light in the blue/ultraviolet part of the electromagnetic spectrum. White light LEDs (“white LEDs”) include one phosphor material which absorbs a portion of the radiation emitted by the LED and re-emits radiation of a different color (wavelength). Typically, the LED die or chip generates blue light in the visible part of the spectrum and the phosphor re-emits yellow light or a combination of green light and red light. The portion of the visible blue light generated by the LED which is not absorbed by the phosphor mixes with the yellow light or the combination of emitted green light and red light to provide light which appears to the eye as being white in color.

Nevertheless, the CCT of a white LED is determined by the light wavelength and power emitted by the blue LED die or chip used therein. Additionally, the color temperature of a white light source utilizing white LED is fixed and decided by the emitting wavelength of the LED chip or die used therein. Thus, the color temperature of the white light source is not adjustable.

Accordingly, a white LED with tunable color temperature is desired to provide, more flexible white light source applications. For example, being able to adjust the white LED for varying conditions of surrounding light.

### BRIEF SUMMARY OF THE INVENTION

Therefore, white light-emitting diode packages with tunable color temperature are provided.

An exemplary white light-emitting diode package with tunable color temperature comprises a package substrate with a first light emitting diode (first LED) disposed over a first portion of the substrate, electrically connected with the package substrate, and a second light emitting diode (second LED) disposed over a second portion different from the first portion of the substrate, electrically connected with the package substrate. A phosphor layer is coated around the first and second LEDs, wherein the phosphor layer is formed by blending at least one colored phosphor grain with a transparent optical resin, and the at least one colored phosphor grain in the transparent optical resin is excited by light from the first and second LEDs to react and emit white light. In one embodiment, the first and second LED are both blue LEDs for emitting blue light of different wavelengths or ultraviolet (UV) LEDs for emitting UV light of different wavelengths.

Another exemplary white light-emitting diode package with tunable color temperature comprises a package substrate with a plurality of conductive pins pairs embedded therein. A first light emitting diode (first LED) is disposed over a first portion of the substrate, electrically connected with one of the conductive pins pairs in the package substrate. A second light emitting diode (second LED) is disposed over a second portion different from the first portion of the substrate, electrically connected with the other one of the conductive pins pairs in the package substrate. A phosphor layer is coated around the first and second LEDs, covering the conductive pin pairs, wherein the phosphor layer is formed by blending at least one colored phosphor grain with a transparent optical resin, and the at least one colored phosphor grain in the transparent optical resin is excited by light from the first and second LEDs to react and emit white light. In one embodiment, the first and second LED are both blue LEDs for emitting blue light of different wavelengths or ultraviolet (UV) LEDs for emitting UV light of different wavelengths.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a stereo diagram of a white light-emitting diode package with tunable color temperature according to an embodiment of the invention;

FIG. 2 is a schematic diagram showing a cross section of the white light-emitting diode package with tunable color temperature taken along a y axis in FIG. 1;

FIG. 3 is a stereo diagram of a white light-emitting diode package with tunable color temperature according to another embodiment of the invention;

FIG. 4 is a schematic diagram showing a cross section of the white light-emitting diode package with tunable color temperature taken along an x axis shown in FIG. 3;

FIG. 5 is a schematic diagram showing a cross section of a white light-emitting diode package with tunable color temperature taken along a y axis shown in FIG. 3; and

FIG. 6 is a simulated Commission Internationale de l'Eclairage (CIE) xy chromaticity diagram indicating chromaticity showing a tunable CCT region of a white light-emitting diode package with tunable color temperature according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

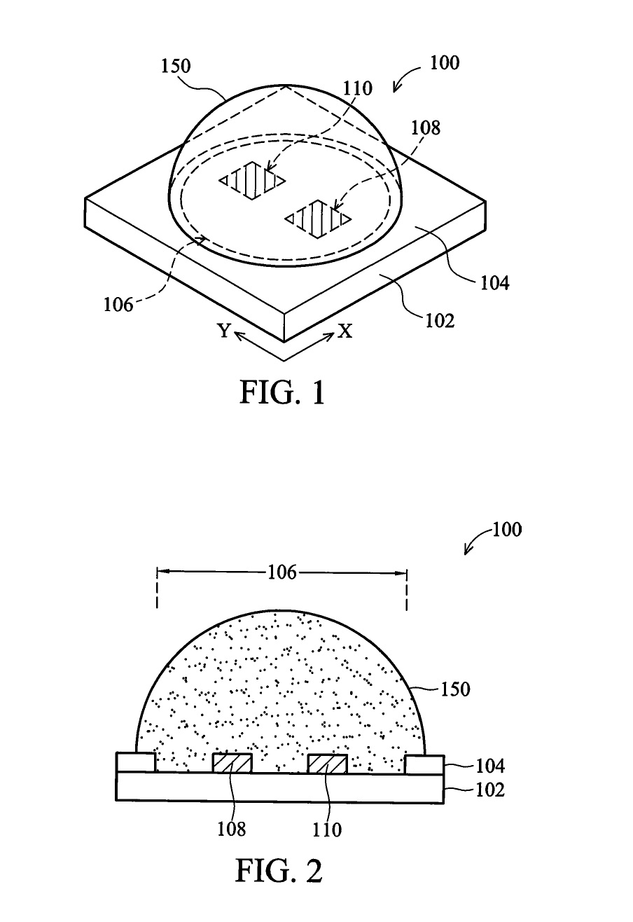

FIGS. 1-2 are schematic diagrams illustrating an exemplary white light-emitting diode package 100 with tunable color temperature.

In FIG. 1, a stereo diagram of the exemplary white light emitting diode package 100 is illustrated, comprising a package substrate 102, a passivation layer 104 defining with a light-emitting area 106 thereover, first and second blue light-emitting diodes (blue LEDs) 108 and 110, and a phosphor layer 150. As shown in FIG. 1, the first blue LED 108 and second blue LED 110 are disposed over the package substrate 102 and are exposed by the light-emitting area 106. The phosphor layer 150 is disposed over the light-emitting area 106, covering the passivation layer 104, the first blue LED 108 and second blue LED 110, and the portions of the package substrate 102 exposed by the passivation layer 104. Structures and functionalities of the components of white LED package 100 in this embodiment will be discussed in detail as follows.

In FIG. 2, a cross section taken along a Y axis in FIG. 1 is illustrated. As shown in FIG. 2, the package substrate 102 can be, for example, a semiconductor substrate or a ceramic substrate with conductive circuits (not shown) formed of conductive electrodes (not shown) or conductive elements therein. Herein, the first blue LED 108 and second blue LED 110 may emit blue light of a wavelength of about 440-480 nm, thereby functioning as a light source for exciting the phosphor layer 150. However, in one embodiment, the blue LED 108 may emit a blue light of a wavelength of about 445˜457.5 nm, which is different from a wavelength of about 472.5˜475 nm of the blue light emitted by the second blue LED 110, thus having a wavelength difference of at least 5 nm therebetween, preferably of about 10-30 nm therebetween. Currents applied to the first blue LED 108 and second blue LED 110 may be the same or different to thereby adjust a CCT of white light emitted by the white LED package 100.

In this embodiment, only a pair of first blue LED 108 and second blue LED 110 are illustrated and provided in the white LED package 100. However, to meet various light intensity requirements, more than one pair of the first blue LED 108 and second blue LED 110 can be formed over the package substrate 102 such as an array configuration (not shown). Additional conductive circuits (not shown) can be also provided over the package substrate 102 so that each of the blue LEDs 108 and 110 are respectively disposed over a corresponding circuit formed over the package substrate 102. The phosphor layer 150 can be a molded phosphor layer provided over the package substrate 102 which surrounds the first blue LED 108 and second blue LED 110. Phosphor grain in the phosphor layer 150 can be excited when blue light emitted from the first blue LED 108 and second blue LED 110 passes therethrough to react and generate white light (not shown).

In one embodiment, the phosphor layer 150 may comprise transparent optical resin blending with phosphor grain of predetermined colors and predetermined ratios. The blue LEDs 108 and 110 may comprise III-V photosemiconductor chips, for example, GaN, InGaAlN or AlGaN chips, and the phosphor layer 150 may comprise transparent resin such as epoxy or silicone gel which is transmissive to blue light and other visible light. The phosphor layer 150 may comprise phosphor grain of yellow color or mixed grain of green and red colors, wherein the yellow phosphor grain may comprise one of YAG, TAG and silicate based phosphor grain, and the green and red phosphor grain may comprise nitride based phosphor. The blue light emitted by the first blue LED 108 and second blue LED 110 may excite mixtures of green and red phosphor grain in the phosphor layer 150 to react and emit green and red lights or may excite the yellow phosphor grain in the phosphor layer 150 to react and emit yellow light. The remaining blue light is then combined with the green and red light, or the yellow light to form a visible white light.

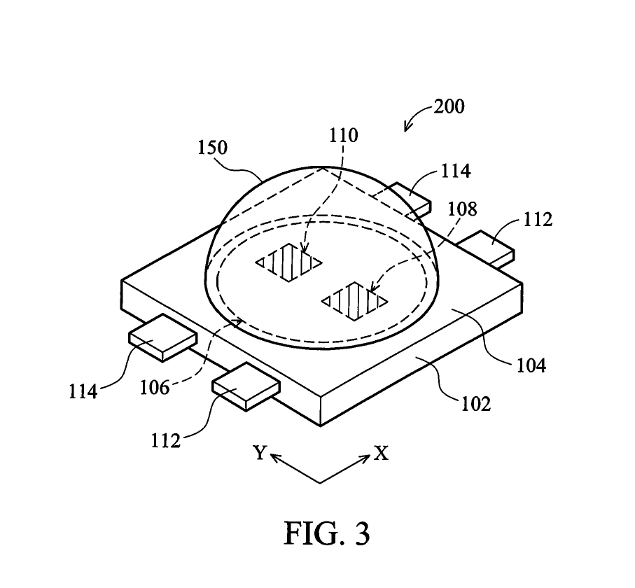

FIGS. 3-5 are schematic diagrams illustrating another exemplary white light-emitting diode package 200 capable of emitting white light of tunable color temperature.

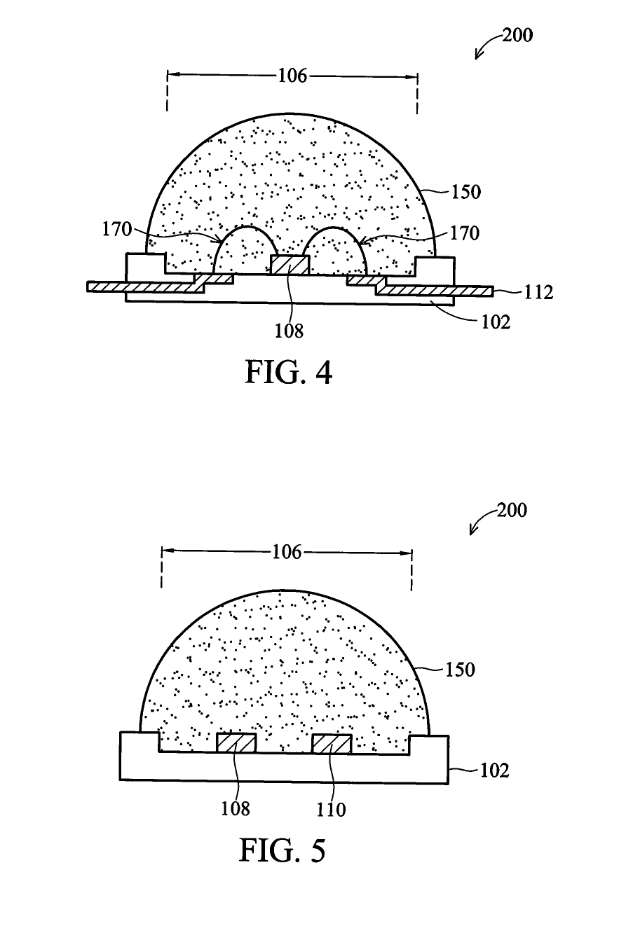

FIG. 3 is a stereo diagram of a white light-emitting diode package 200 and FIGS. 4 and 5 are schematic diagrams showing various cross sections of the white light-emitting diode package 200 along x axis and y axis, respectively.

In this embodiment, the white light-emitting diode package 200 is similar with the white LED 100 illustrated in FIGS. 1 and 2, wherein same numeral titles in FIGS. 3-5 represent the same components. For simplicity, only differences between the white LED package 200 and the white LED package 100 are discussed below.

In FIGS. 3 and 4, additional pairs of conductive pins 112 and 114 are provided in the package substrate 102 of the white LED package 200 for electrically connecting the first blue LED 108 and second blue LED 110, respectively. As shown FIG. 3, the pair of conductive pins 112 is disposed to electrically connect with an anode and a cathode (both not shown) of the first blue LED 108, and the pair of conductive pins 114 is disposed to electrically connect with an anode and a cathode (both not shown) of the second blue LED 110. As shown in FIG. 4, the package substrate 102 is now formed with no conductive circuits therein and the anode and the cathode (both not shown) of the first blue LED 108 is electrically connected with one of the conductive pins 112 by a wire bond 170, respectively. The conductive pins 112 respectively penetrate through the package substrate 102 along opposite sidewalls thereof and may be parts of a lead frame (not shown) which is embedded within the package substrate 102. FIG. 5 shows another cross section of the white LED package 200 taken along the y axis in FIG. 3. As shown in FIG. 5, the pair of conductive pins 112 and 114 is not illustrated and only the first blue LED 108 and second blue LED 110 are illustrated. In this embodiment, currents applied to the pair of the conductive pins 112 and 114 may be the same or different, and the first blue LED 108 and second blue LED 110 receive the same or different current.

In other exemplary embodiments, the first blue LED 108 and second blue LED 110 in the white LED packages 100 and 200 may be replaced by a first ultraviolet (UV) LED and a second UV LED (both not shown), respectively for emitting a UV light of a wavelength of about 390˜392.5 nm and 405-407.5 nm, and the phosphor layer 150 may comprise transparent optical resin blended with phosphor grain of red, green, blue, and orange colors, thereby emitting a visible white light.

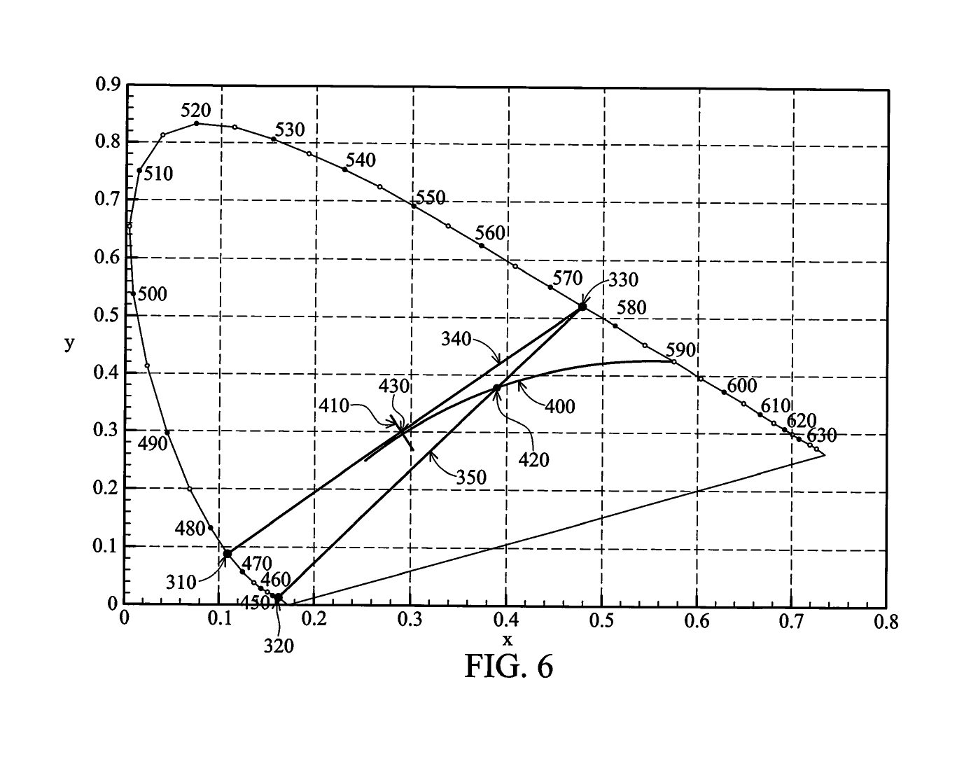

In an alternative white LED package 100 or 200 illustrated in FIGS. 1-2 and FIGS. 3-5, respectively, the first blue LED 108 and second blue LED 110 are operable to emit different colored light (that is other than white) with the use of a phosphor layer 150 comprising yellow phosphor grain which when combined together comprises light which appears to be white in color. In one such light source, the first blue LED 108 emits a first blue light (of a wavelength 445 nm) with chromaticity coordinates CIE (x, y) of (0.1611, 0.0138), the second blue LED 110 (of a wavelength 475) emits a second blue light with chromaticity coordinates CIE (x, y) of (0.1096, 0.0868), and the phosphor layer 150 comprising yellow phosphor grain is provided with chromaticity coordinates CIE (x, y) of (0.475, 0.516). Again the color temperature of the output white light is tuned by controlling the relative magnitude of the current applied to the first and second blue LEDs. FIG. 6 is a simulated Commission Internationale de l'Eclairage (CIE) 1931 xy chromaticity diagram for such a source indicating the chromaticity coordinates 310, 320, and 330 for the first blue LED 108 and second blue LED 110 and the phosphor layer 150, respectively. An intersection 430 of an 8000K isothermal line 410 and line 340 which connects the chromaticity coordinates of the first blue LED 108 and the phosphor layer 150 represents a possible high color temperature of 8000K of output white light of the source can be generated by changing the magnitude of the drive currents, and an intersection 420 between the blackbody curve 400 and another line 350 connecting the chromaticity coordinates of the second blue LED 110 and the phosphor layer 150 represent a possible low color temperature of 3700K of output white light of the source can be generated by changing the magnitude of the drive currents. An advantage of using two blue LEDs with different wavelengths to generate white light is for improved performance. A tunable color temperature of between 3700-8000 K is thus obtained.

As discussed above, the white LED packages of the invention have the following advantages.

1. A CCT of a white light source utilizing the white LED package of the invention is adjustable between a range of about 2750˜10000K, thus, expanding application of the white light source for varying conditions of surrounding light.

2. The CCT of a white light source utilizing the white LED package can be suitable adjusted according to type of the LED chip or die and the phosphor grain used therein.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A white light-emitting diode (LED) package with tunable color temperature, comprising
a package substrate;
a first light emitting diode (first LED) disposed over a first portion of the substrate, electrically connected with the package substrate;
a second light emitting diode (second LED) disposed over a second portion different from the first portion of the substrate, electrically connected with the package substrate; and
a phosphor layer coated around the first and second LEDs, wherein the phosphor layer is formed by blending at least one colored phosphor grain with a transparent optical resin, and the at least one colored phosphor grain in the transparent optical resin is excited by light from the first and second LEDs to react and emit white light,
wherein the first and second LED are both blue LEDs for emitting blue light of different wavelengths or ultraviolet (UV) LEDs for emitting UV light of different wavelengths.

2. The white LED package as claimed in claim 1, wherein the first and second LEDs emit light with a wavelength difference of at least 5 nm.

3. The white LED package as claimed in claim 2, wherein the first and second LEDs emit light with a wavelength difference of 10-30 nm.

4. The white LED package as claimed in claim 1, wherein the first and second LED are blue LEDs and the phosphor layer comprises phosphor grain of yellow color.

5. The white LED package as claimed in claim 1, wherein the first and second LED are blue LEDs and the phosphor layer comprises phosphor grain of green and red colors.

6. The white LED package as claimed in claim 1, wherein the first and second LED are UV LEDs and the phosphor layer comprises phosphor grain of blue, green, red and orange colors.

7. The white LED package as claimed in claim 1, wherein the package substrate comprises semiconductor materials or ceramic materials.

8. The white LED package as claimed in claim 1, wherein an adjustable color temperature of the white light is in a range between 2750-10000K.

9. The white LED package as claimed in claim 8, wherein an adjustable color temperature of the white light is in a range between 3700-8000K.

10. A white LED package with tunable color temperature, comprising
a package substrate with a plurality of conductive pins pairs embedded therein;
a first light emitting diode (first LED) disposed over a first portion of the substrate, electrically connected with one of the conductive pins pairs in the package substrate;
a second light emitting diode (second LED) disposed over a second portion different from the first portion of the substrate, electrically connected with the other one of the conductive pins pairs in the package substrate; and
a phosphor layer coated around the first and second LEDs, covering the conductive pin pairs, wherein the phosphor layer is formed by blending at least one colored phosphor grain with a transparent optical resin, and the at least one colored phosphor grain in the transparent optical resin is excited by light from the first and second LEDs to react and emit white light,
wherein the first and second LED are both blue LEDs for emitting blue light of different wavelengths or ultraviolet (UV) LEDs for emitting UV light of different wavelengths.

11. The white LED package as claimed in claim 10, wherein the first and second LEDs emit light with a wavelength difference of at least 5 nm.

12. The white LED package as claimed in claim 11, wherein the first and second LEDs emit light with a wavelength difference of 10-30 nm.

13. The white LED package as claimed in claim 10, wherein the first and second LED are blue LEDs and the phosphor layer comprises phosphor grain of yellow color.

14. The white LED package as claimed in claim 10, wherein the first and second LED are blue LEDs and the phosphor layer comprises phosphor grain of green and red colors.

15. The white LED package as claimed in claim 10, wherein the first and second LED are UV LEDs and the phosphor layer comprises phosphor grain of blue, green, red and orange colors.

16. The white LED package as claimed in claim 10, wherein the package substrate comprises lead frame.

17. The white LED package as claimed in claim 10, wherein an adjustable color temperature of the white light is in a range between 2750-10000 K.

18. The white LED package as claimed in claim 17, wherein an adjustable color temperature of the white light is in a range between 3700-8000K.
